(19) United States
(12) Patent Application Publication
(10) Pub. No.: US 2006/0022276 A1
(43) Pub. Date: Feb. 2, 2006

(54) Methods of forming semiconductor devices including a resistor in a resistor region and devices so formed

(76) Inventors: Jin-taek Park, Gyeonggi-do (KR); Jung-dal Choi, Gyeonggi do (KR); Sung-hoi Hur, Seoul (KR); Joon-hee Lee, Gyeonggi-do (KR)

Correspondence Address: MYERS BIGEL SIBLEY & SAJOVEC, PO BOX 37428, RALEIGH, NC, 27627, US

(21) Appl. No.: 11/023,892

(22) Filed: Dec. 28, 2004

(30) Foreign Application Priority Data
Jul. 29, 2004 (KR) 2004-59811

(51) Int. Cl. H01L 29/94

(52) U.S. Cl. 257/368

(57) ABSTRACT

Methods of forming a semiconductor device can include forming a first conductive layer of a gate electrode on a substrate of a device and forming a second conductive layer of a resistor, that is different than the first conductive layer, on the substrate spaced-apart from the gate electrode. Related devices are also disclosed.

### CROSS-REFERENCE TO RELATED APPLICATIONS

This U.S. non-provisional patent application claims priority under 35 U.S.C. § 119, to Korean Patent Application 2004-59811 filed on Jul. 29, 2004, the entire contents of which are hereby incorporated by reference.

### FIELD OF THE INVENTION

The present invention relates to semiconductor devices and methods of forming the same and, more specifically, to semiconductor devices including a resistor and methods of forming the same.

### BACKGROUND

Most electronic devices, such as televisions, telephones, radios and computers, use semiconductor products such as capacitors, diodes, resistors, etc. It is known to form resistors to have a specific resistance in accordance with a use in the semiconductor products. Specifically, resistors may be formed to a certain size to provide a specified value.

Some products may call for the inclusion of resistors that have relatively large resistance values, which may be difficult to form as the conductive materials typically used in the product have a relatively low resistivity (such as materials used to provide interconnections within an integrated circuit). Unfortunately, as resistor that uses such low resistivity materials may be too large to practically include in the product.

It is known to form resistors in semiconductor products using other materials (e.g., polysilicon) that can also be used as a gate electrode, a contact plug, etc. Using polysilicon (one material used in fabricating semiconductor devices) having suitable resistance enables the semiconductor device including a resistor to be fabricated while maintaining needed chip areas.

A semiconductor device including a resistor comprising polysilicon and a method of forming the same is discussed in Korea Patent Application No. 10-2003-0014385, which describes a method of forming the resistor with the same material as the floating gate electrode of the flash memory. The method includes a step of forming the floating gate electrode by means of a specific photolithographic etching process. However, as a highly integrated the semiconductor device, a method without using the photolithographic etching process is disclosed in 2003 Symposium on VLSI Technology Digest Of Technical Papers”, pp. 89-90, entitled “A novel self-aligned shallow trench isolation cell for 90 nm 4 Gbit NAND Flash EEPROMs”. According to this paper, the polysilicon layer used as the floating gate electrode is entirely removed from a device isolating layer on the peripheral circuit region where the resistor is formed conventionally. Therefore, it may be difficult to form the resistor using the same process used to form the floating gate.

Meanwhile, the control gate electrode includes a metal layer so as to improve speed of a device generally. Therefore, when the material used for the control gate electrode is also used to form a resistor, the resistor should be relatively long due to the relatively low resistance. As discussed above, this approach may adversely impact the integration level of the semiconductor device.

### SUMMARY

Embodiments according to the invention can provide methods of forming semiconductor devices including a resistor in a resistor region and devices so formed. Pursuant to these embodiments, a method of forming a semiconductor device can include forming a first conductive layer of a gate electrode on a substrate of a device and forming a second conductive layer of a resistor, that is different than the first conductive layer, on the substrate spaced-apart from the gate electrode.

In some embodiments according to the invention, forming a first conductive layer can include doping the first conductive layer with a first level of impurities, wherein forming a second conductive layer includes doping the second conductive layer with a second level of impurities. In some embodiments according to the invention, doping the second conductive layer includes doping the second conductive layer to the second level that is less than the first layer.

In some embodiments according to the invention, forming a second conductive layer includes forming the second conductive layer at a level in the device above the first conductive layer. In some embodiments according to the invention, a method can further include forming a first contact coupled between a bit line and a conductive region in the substrate coupled to the device including the first conductive layer and forming a second contact coupled between the resistor and a conductive pattern positioned at the same level with the bit line.

In some embodiments according to the invention, a method can further include forming a layer on the first conductive layer and on the substrate in the resistor region prior to forming the second conductive layer. In some embodiments according to the invention, forming a layer can include forming an etch stop layer, an insulating layer and/or a planarized interlevel dielectric layer on the first conductive layer and on the substrate in the resistor region prior to forming the second conductive layer.

In some embodiments according to the invention, a method can further include forming a device isolating layer on the substrate in the resistor region. In some embodiments according to the invention, a method can further include forming an etch stop layer on the first conductive layer and on the resistor and removing the etch stop layer from the first conductive layer and maintaining a portion of the etch stop layer on the resistor.

In some embodiments according to the invention, a method of forming a resistor in a semiconductor device can include forming a first conductive layer of a gate electrode on a cell array region of a substrate of a device. An etch stop layer can be formed on the first conductive layer and a second conductive layer can be formed on the etch stop layer so that the first and second conductive layers are separated from one another by the etch stop layer. Te second conductive layer can be etched from on the first conductive layer and maintaining a portion of the second conductive layer to form a resistor on a resistor region of the substrate spaced-apart from the cell array region.

In some embodiments according to the invention, a method can further include forming a second etch stop layer on the first and second conductive layers prior to etching, wherein etching the second conductive layer comprises etching the second conductive layer and the second etch stop layer from on the first conductive layer and maintaining a portion of the second etch stop layer and second conductive layer to form the resistor in the resistor region.

In some embodiments according to the invention, a method can further include forming an interlevel dielectric layer on the etch stop layer prior to forming the second conductive layer so that the interlevel dielectric layer is located between the second conductive layer and the etch stop layer. In some embodiments according to the invention, the method can further include forming a second etch stop layer on the second conductive layer, wherein etching the second conductive layer comprises etching the second conductive layer and the second etch stop layer from on the interlevel dielectric layer over the first conductive layer and maintaining a portion of the second etch stop layer and second conductive layer to form the resistor in the resistor region. In some embodiments according to the invention, forming an etch stop layer can include forming an insulating layer.

In some embodiments according to the invention, forming can include doping the first conductive layer with a first level of impurities and doping the second conductive layer with a second level of impurities. In some embodiments according to the invention, forming a first conductive layer can include forming a floating gate electrode and/or a control gate electrode. In some embodiments according to the invention, a method further includes forming a control gate electrode on a floating including a third conductive layer separate from the first and second conductive layers.

In some embodiments according to the invention, a semiconductor device can include a first conductive layer of a gate electrode on a substrate of a device and a second conductive layer of a resistor, that is different than the first conductive layer, on the substrate spaced-apart from the gate electrode.

In some embodiments according to the invention, a semiconductor device can include a substrate including a cell array region and a resistor region. A cell gate pattern including a gate oxide layer, a floating gate layer, a gate dielectric layer and a control gate layer are sequentially stacked on the semiconductor substrate of the cell array region. A resistor is located over the semiconductor substrate of the resistor region, wherein the floating gate layer is formed of a first conductive layer, the control gate layer is formed of a second conductive layer, and the resistor is formed of a third conductive layer.

### BRIEF DESCRIPTION OF THE DRAWINGS

FIG. 1A is a cross-sectional view of a semiconductor device including a resistor according to some embodiments of the present invention.

FIG. 1B is a cross-sectional view of a semiconductor device including a resistor according to some embodiments of the present invention.

FIGS. 2 through 4 are cross-sectional views illustrating methods of forming a semiconductor device including a resistor according to some embodiments of the invention.

FIG. 5 is a cross-sectional view of a semiconductor device including a resistor according to some embodiments of the present invention.

FIG. 6 is a cross-sectional view illustrating embodiments of methods of forming a semiconductor device including a resistor in FIG. 5 according to the present invention.

FIG. 7A is a cross-sectional view that illustrates semiconductor devices including a resistor in some embodiments according to the present invention.

FIG. 7B is a cross-sectional view that illustrates semiconductor devices including a resistor in some embodiments according to the present invention.

FIGS. 8 and 9 are cross-sectional view that illustrate methods of forming the semiconductor device in FIG. 7A in some embodiments according to the present invention.

### DESCRIPTION OF EMBODIMENTS ACCORIDNG TO THE INVENTION

The present invention will be described more fully hereinafter with reference to the accompanying drawings, in which exemplary embodiments of the invention are shown. However, this invention should not be construed as limited to the embodiments set forth herein. Rather, these embodiments are provided so that this disclosure will be thorough and complete, and will fully convey the scope of the invention to those skilled in the art. In the drawings, the thickness of layers and regions are exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It will also be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present invention.

Furthermore, relative terms, such as “lower” or “bottom” and “upper” or “top,” may be used herein to describe one element's relationship to another elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending of the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

The terminology used in the description of the invention herein is for the purpose of describing particular embodiments only and is not intended to be limiting of the invention. As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

Embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing. The regions illustrated in the figures are schematic in nature and their shapes are not intended to illustrate the actual shape of a region of a device and are not intended to limit the scope of the invention.

Unless otherwise defined, all terms used in disclosing embodiments of the invention, including technical and scientific terms, have the same meaning as commonly understood by one of ordinary skill in the art to which this invention belongs, and are not necessarily limited to the specific definitions known at the time of the present invention being described. Accordingly, these terms can include equivalent terms that are created after such time. All publications, patent applications, patents, and other references mentioned herein are incorporated by reference in their entirety.

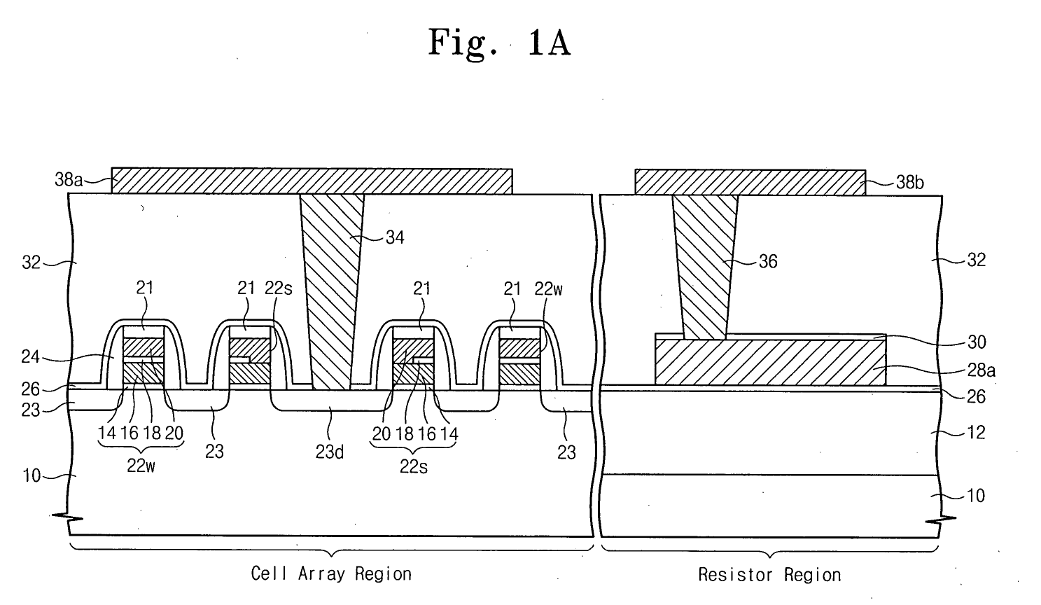

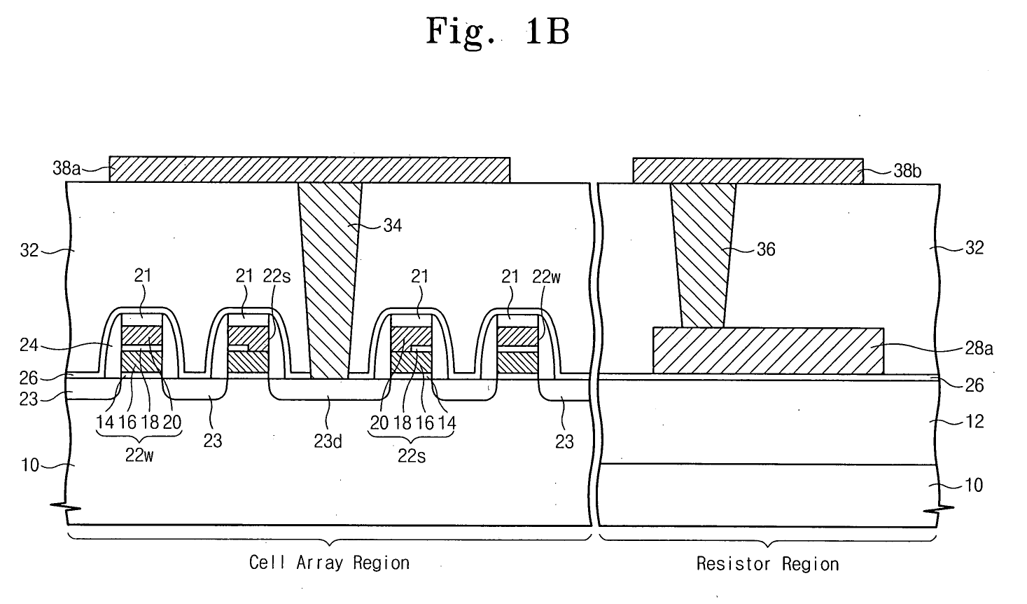

FIG. 1A is a cross-sectional view that illustrates semiconductor memory devices including a resistor in some embodiments according to the present invention. Referring to FIG. 1A, a device isolating layer 12 is disposed in a semiconductor substrate 1 including a cell array region and a resistor region to define an active region. It will be understood that the resistor region can be located in what is sometimes referred to as the peripheral region of the semiconductor memory device. In case of a NAND flash memory device, the device isolating layer 12 crosses over the active region at the cell array region and may have a structure comprised of a plurality of lines that are parallel to each other. A plurality of gate patterns 22w and 22s are disposed on the cell array region. More specifically, a plurality of word lines 22w, string selection lines 22s, ground selection lines (not shown) are disposed to cross over the device isolating layer 12.

The cell gate patterns 22w and 22s may include a gate oxide layer 14, a floating gate layer 16, a gate dielectric layer 18 and a control gate layer 20 that are sequentially stacked. The string selection line 22s and the ground selection line (not shown) may include an identical component. The gate dielectric layer 18 included in the lines is shorter than that in the word line 22w, such that the floating gate layer 16 and the control gate layer 20 may contact each other. Alternately, the gate dielectric layer 18 may not exist in the line. Capping spacers 21 are disposed to cover upper parts and sidewalls of the lines 22w and 22s. Impurity regions 23 and 23d are in the active region between the lines. The impurity region between the string selection lines 22s is referred to as ‘a common drain region 23d’. The common source region is disposed in the active region between the ground selection lines, but is not illustrated in FIG. 1A.

Referring to FIG. 1A, a first etch stop layer 26 is disposed to cover the cell gate patterns 22w and 22s and the device isolating layer 12. A resistor 28a is disposed on the first etch stop layer 26 in the resistor region. The second etch stop layer 30 may be on the resistor 28a. An interlayer insulating layer 32 is disposed to cover the cell gate patterns 22w and 22s and the resistor 28a. The bit line contact 34 penetrates the interlayer insulating layer 32 and the first etch stop layer 26 to contact the common drain region 23d. The resistor contact 36 penetrates the interlayer insulating layer 32 and the second etch stop layer 30 to contact the resistor 28a. The bit line contact 34 is connected to a bit line 38a, and the resistor contact 36 is connected to a conductive pattern 38b which is formed of the same materials as the bit line 38a.

In some embodiments according to the invention, the gate dielectric layer 18 may be a triple layer comprising an oxide layer, a nitride layer and an oxide layer. In some embodiments according to the invention, the capping layer 21 and the spacer 24 may be formed of a silicon nitride layer, a silicon oxide layer and/or a silicon oxynitride layer. The etch stop layers 26 and 30 are formed of a material having etch selectivity with respect to the interlayer insulating layer 32. In some embodiments according to the invention, the etch stop layers 26 and 30 are formed of silicon nitride and/or silicon oxynitride.

In some embodiments according to the invention, the interlayer insulating layer 32 may be formed using Hydrogen Silsesquioxane (HSQ), Boron Phosphorus Silicate Glass (BPSG), High density plasma (HDP) oxide, plasma enhanced tetraethyl orthosilicate (PETEOS), Undoped Silicate Glass (USG), Phosphorus Silicate Glass (PSG), PE-SiH₄ and/or Al₂O₃ using Plasma-enhanced chemical vapor deposition (PECVD), Low-pressure chemical vapor deposition (LPCVD), Atomic layer deposition (ALD) and/or Spin on glass (SOG).

The resistor 28a is formed of conductive material that is different than the gate layers 16 and 20 included in the cell gate patterns 22w and 22s. Specifically, the floating gate layer 14 is formed of a first conductive layer, such as, polysilicon with or without doped impurities. The control gate layer 20 is formed of a second conductive layer, such as polysilicon with or without doping, tungsten, tungsten silicide and/or tungsten nitride. In some embodiments according to the invention, the resistor 28a is formed of a third conductive layer, such as polysilicon (with or without doping). Since the resistor 28a is formed of a material that is different from the gate layers 16 and 20 included in the cell gate patterns 22w and 22s, it may not be restricted by characteristics of the gate layer and sheet resistance.

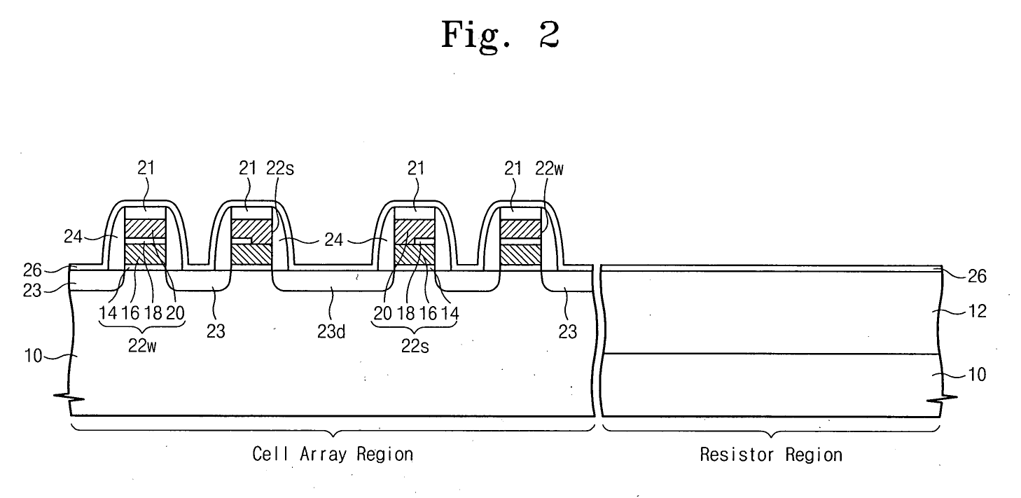

FIGS. 2 through 4 are cross-sectional views illustrating methods of forming a semiconductor device illustrated by FIG. 1A according to some embodiments of the invention. Referring to FIG. 2, a device isolating layer 12 and cell gate patterns 22w and 22s are formed on the semiconductor substrate including a cell array region and a resistor region (or peripheral region).

A gate oxide layer 14 and a first conductive layer 16 are stacked on the semiconductor substrate 10 and patterned to form a trench for defining an active region. A device isolating layer 12 is formed by filling the trench with insulating material and planarized to expose the first conductive layer 16. A gate dielectric layer 18, a second conductive layer 20 and a capping layer 21 are formed on a surface of the semiconductor substrate 10 and patterned to form cell gate patterns 22w and 22s and to expose the device isolating layer 12 of the resistor region. Using the cell gate patterns 22w and 22s as an ion implantation mask, impurity regions 23 and 23d are formed in the active region. A spacer layer is stacked and etched anisotropically to form spacers 24 covering sidewalls of the cell gate patterns 22w and 22s. A first etch stop layer 26 is formed on the cell array region and on the resistor region of the semiconductor substrate 10.

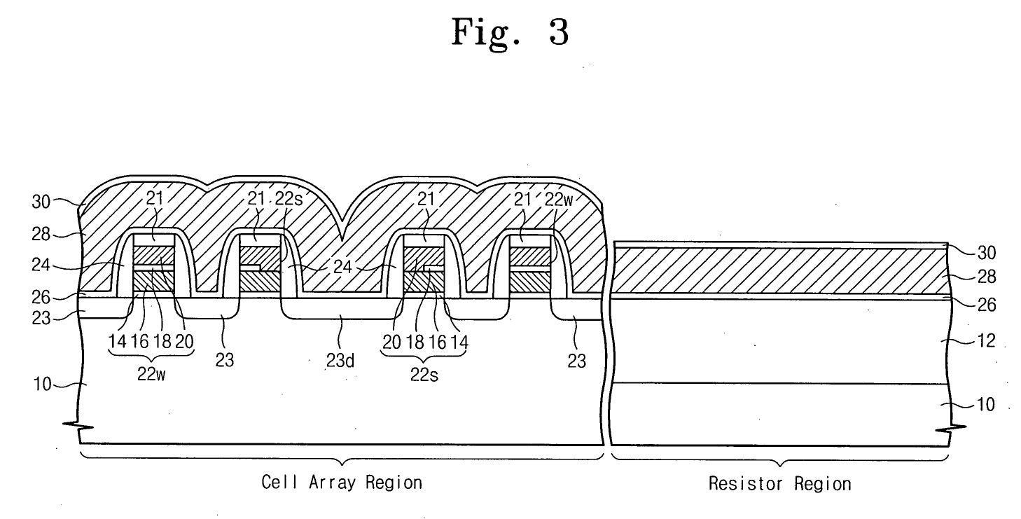

Referring to FIG. 3, a third conductive layer 28 and a second etch stop layer 30 are formed on the first etch stop layer 26. In some embodiments according to the invention, the third conductive layer 28 is formed of polysilicon (with or without doped impurities). The third conductive layer 28 may be formed by depositing a doped polysilicon layer or by doping after the polysilicon layer is formed. A thickness or doping concentration of the third conductive layer 28 may vary according to characteristics of the process.

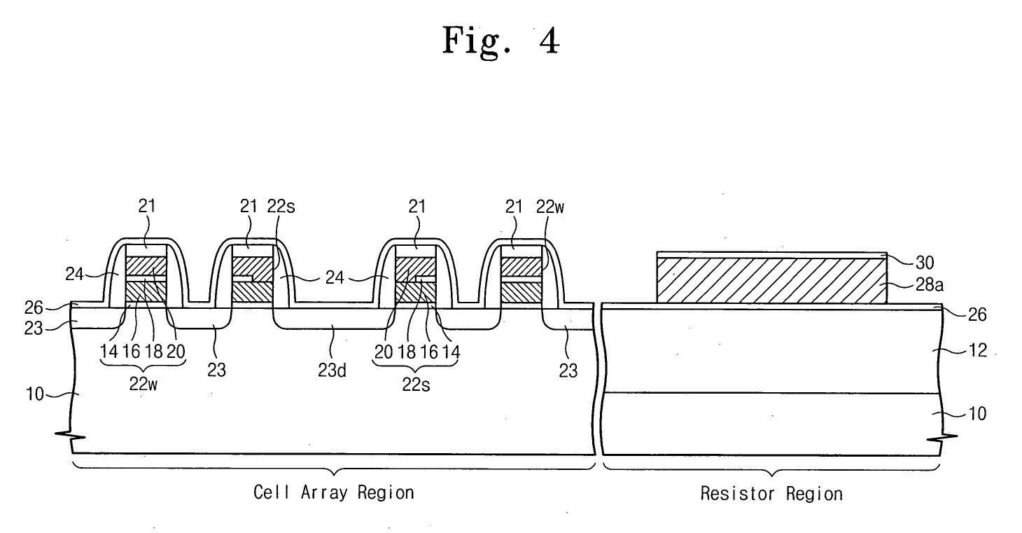

Referring to FIG. 4, the second etch stop layer 30 and the third conductive layer 28 are sequentially etched by means of a photoresist pattern (not shown), thereby exposing the first etch stop layer 26 in the cell array region and forming a resistor 28a on the device isolating layer 12 in the resistor region. In some embodiments according to the invention, the first etch stop layer 26 protects the cell gate patterns 22s and 22w and the semiconductor substrate 10 on both sides thereof.

An interlayer insulating layer (shown in FIG. 1A) is formed and patterned by means of the photoresist pattern (not shown) to expose the first etch stop layer 26 on the common drain region 23d (through, for example, a contact hole in the interlayer insulating layer) and to expose the second etch stop layer 30 on the resistor 28a. In some embodiments according to the invention, the first etch stop layer 26 protects the cell array region and the second etch stop layer 30 protects the resistor 28a. The exposed first etch stop layer 26 (through the interlayer insulating layer) and the second etch stop layer 30 are removed to form a bit line contact hole and a resistor contact hole. The contact holes are filled with conductive material to form a bit line contact 34 and a resistor contact 36. A conductive layer is stacked and patterned to form a bit line 38a and a conductive pattern 38b.

In some embodiments according to the invention, the resistor 28a, the cell gate patterns 22w and 22s are formed from separate layers. In some embodiments according to the invention, the layer providing the resistor 28a is formed after the cell gate patterns 22w and 22s are formed. Therefore, it may be easier to adjust the resistor value with fewer restrictions associated with the characteristics of the gate layer included in the cell gate patterns 22w and 22s.

FIG. 1B is a cross-sectional view that illustrates semiconductor devices including a resistor in some embodiments according to the present invention. In particular, the second etch stop layer 30 shown in FIG. 1A is absent from the present embodiments according to the invention. For example, the semiconductor device of FIG. 1B may be embodied by forming and patterning the third conductive layer 28 without the second etch stop layer 30.

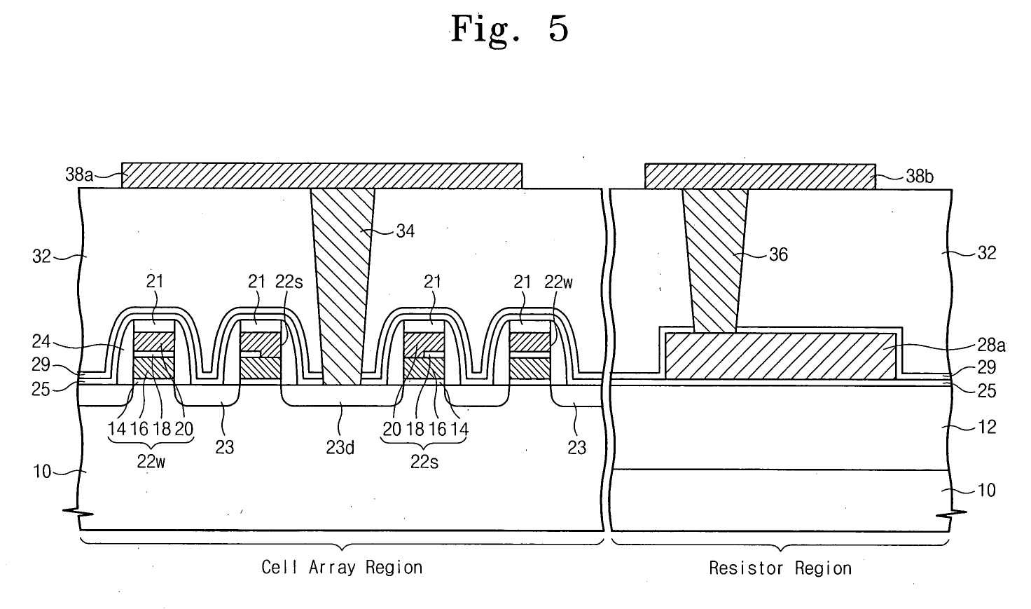

FIG. 5 is a cross-sectional view that illustrates semiconductor devices including a resistor in some embodiments according to the invention. Referring to FIG. 5, cell gate patterns 22s and 22w are conformally covered with a double layer of an insulating layer 25 and an etch stop layer 29. The insulating layer 25 and the etch stop layer 29 are located in the resistor region having a resistor 28a therebetween. In some embodiments according to the invention, the insulating layer may be a medium temperature oxide (MTO), a High density plasma (HDP) oxide, a plasma enhanced tetraethyl orthosilicate (PETEOS, Undoped Silicate Glass (USG), Phosphorus Silicate Glss (PSG), PE-SiH₄ and/or Al₂O₃. In some embodiments according to the invention, the etch stop layer 29 may be formed of the same material as the etch stop layers 26 and 30 as described above in reference to FIGS. 1A, 1B and 2-4. A bit line contact 34 penetrates the interlayer insulating layer 32, the etch stop layer 29 and the insulating layer 25 to contact the common drain region 23d. A resistor contact 36 penetrates the interlayer insulating layer 32 and the etch stop layer 29 to contact the resistor 28a.

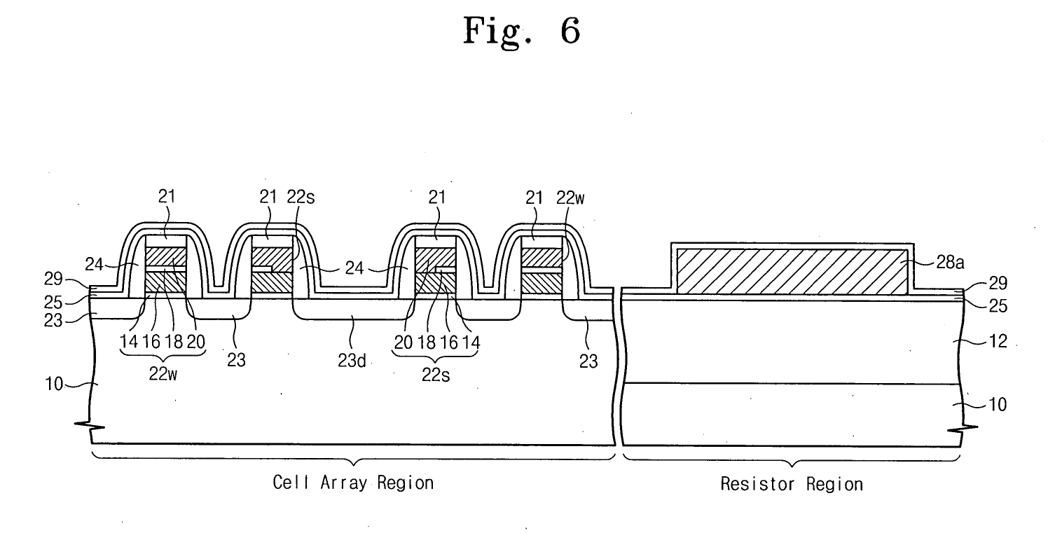

FIG. 6 is a cross-sectional view illustrating methods of forming the semiconductor device in FIG. 5. Referring to FIG. 6, an insulating layer 25 may be conformally formed on a surface of the semiconductor substrate 10 having spacers covering sidewalls of the cell gate pattern 22s and 22w. The insulating layer 25 may compensate for etch damage to the semiconductor substrate 10 which may occur during the forming of the spacers 24.

A third conductive layer (28 in FIG. 3) is stacked on the surface of the semiconductor substrate 10 including on the conformal insulating layer 25 and patterned to form the resistor 28a in the resistor region. An etch stop layer 29 is conformally deposited on a surface of the resultant structure. The etch stop layer 29 may help protect the semiconductor substrate 10 of the cell array region and the resistor 28a when the bit line contact hole and the resistor contact hole are formed by patterning the subsequent interlayer insulating layer 32. The subsequent process may be the same described above in reference to FIGS. 2-4.

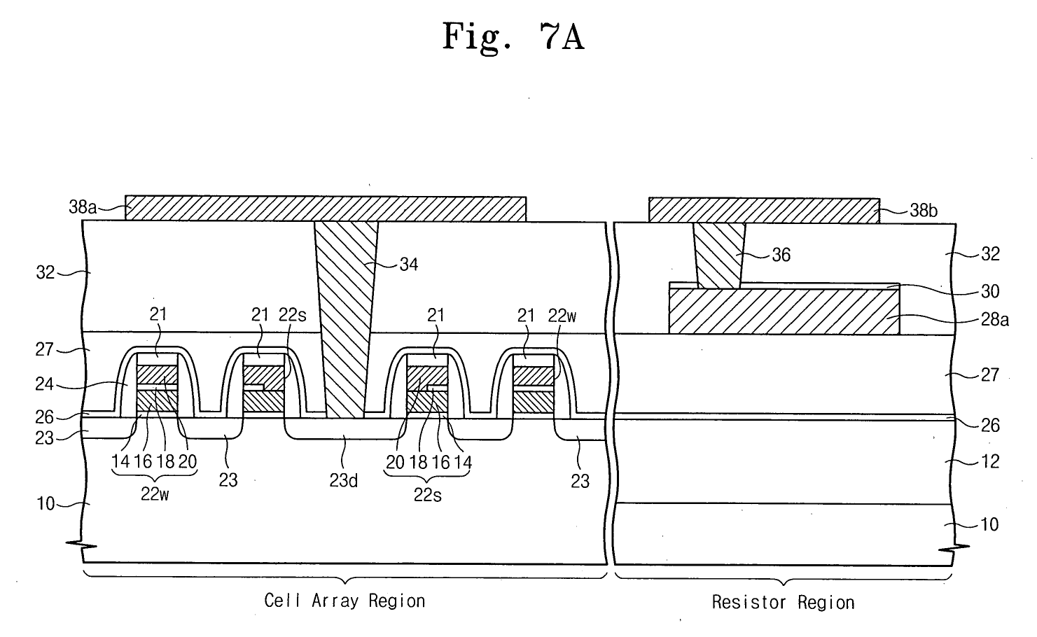

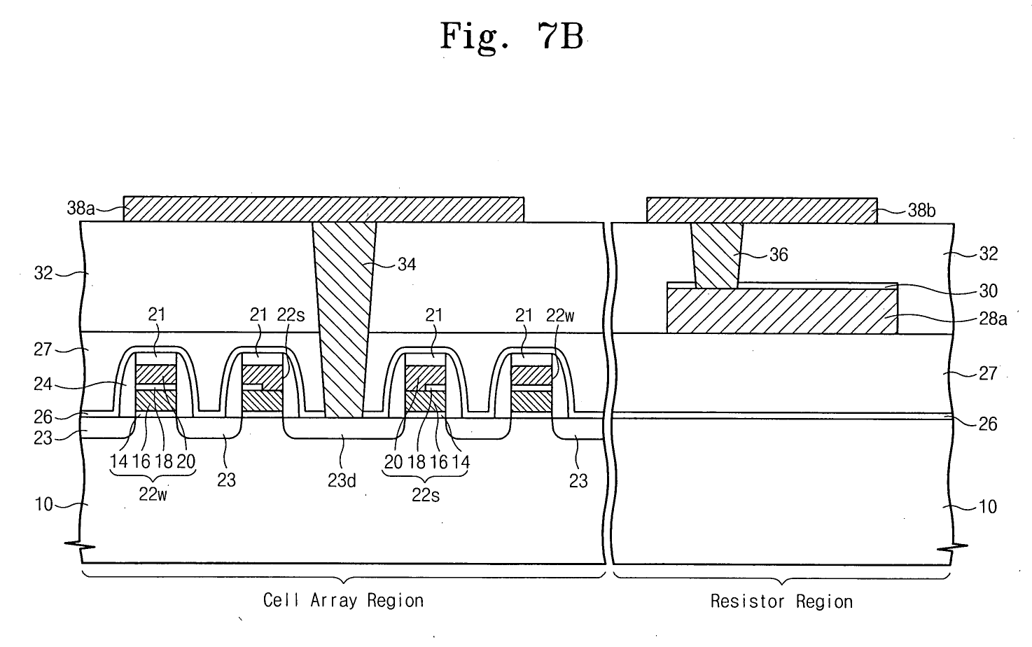

FIG. 7A is a cross-sectional view that illustrates semiconductor devices including a resistor in some embodiments according to the present invention. Referring to FIG. 7A, the resistor 28a is disposed on a lower interlayer insulating layer 27 covering the cell gate patterns 22w and 22s. In some embodiments according to the invention, the resistor 28a is on the lower interlayer insulating layer 27 at a height above the cell gate patterns 22w and 22s. In still other embodiments according to the invention, the resistor 28a is on the lower interlayer insulating layer 27 so that a base thereof is above the cell gate patterns 22w and 22s.

In some embodiments according to the invention, the lower interlayer insulating layer 27 may be formed of the same material as the interlayer insulating layer 32 described above. The bit line contact 34 penetrates the interlayer insulating layer 32, the lower interlayer insulating layer 27, and the first etch stop layer 26 to contact the common drain region 23d.

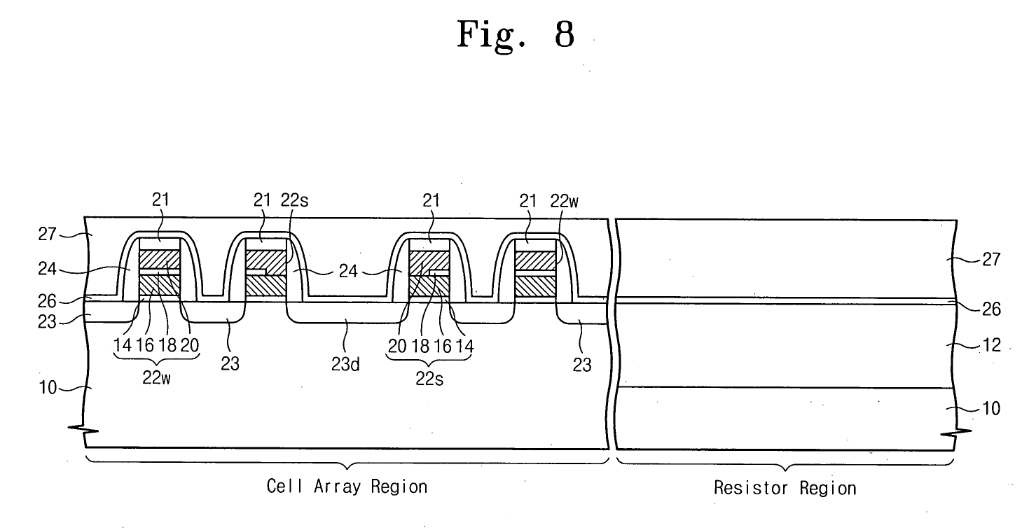

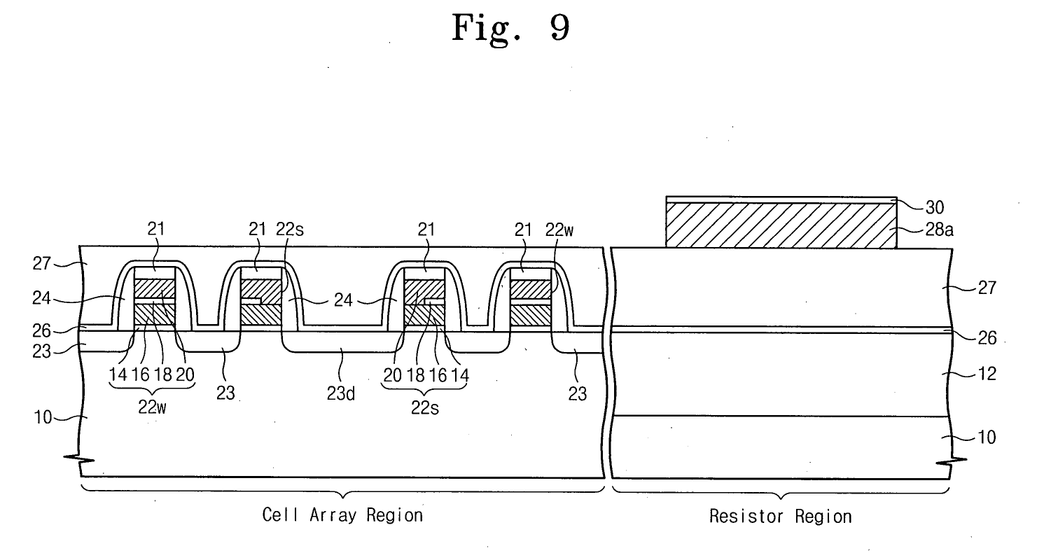

FIGS. 8 and 9 are cross-sectional views that illustrate methods of forming a semiconductor device shown in FIG. 7A. Referring to FIG. 8, a lower interlayer insulating layer 27 is stacked on a surface of the semiconductor substrate 10 shown in FIG. 2. An upper portion of the lower interlayer insulating layer 27 may be planarized by means of a chemical mechanical polishing (CMP) method, or other process.

Referring to FIG. 9, a third conductive layer 28 and a second etch stop layer 30 are formed on one another on the lower interlayer insulating layer 27 and patterned using a photoresist pattern (not shown), thereby forming a resistor 28a in the resistor region. Subsequent processes may be the same as those described above with reference to FIGS. 2-4.

FIG. 7B is a cross-sectional view that illustrates semiconductor devices including a resistor in some embodiments according to the present invention. In particular, the device isolating layer 12 shown, for example, in FIG. 7A is not present under the resistor 28a. The lower interlayer insulating layer 27 should be thick enough to prevent leakage current. In some embodiments according to the invention, for example, the thickness of the lower interlayer insulating layer 27 is greater than about 2000 Angstroms.

According to methods of forming resistors in semiconductor devices according to embodiments of the present invention, a resistor is formed with a material layer in a resistor region after a cell gate pattern in a cell array region is formed. Therefore, a resistor value can be adjusted with fewer restrictions implied by characteristics of the gate layer in the cell gate pattern. In addition, a regular sheet resistor value may be achieved and a chip area may be reduced.

Although the present invention has been described in connection with the embodiment of the present invention illustrated in the accompanying drawings, it is not limited thereto. It will be apparent to those skilled in the art that various substitution, modifications and changes may be thereto without departing from the scope and spirit of the invention.

1. A method of forming a semiconductor device comprising:
forming a first conductive layer of a gate electrode on a substrate of a device; and
forming a second conductive layer of a resistor, that is different than the first conductive layer, on the substrate spaced-apart from the gate electrode.

2. A method according to claim 1 wherein forming a first conductive layer comprises doping the first conductive layer with a first level of impurities; and
wherein forming a second conductive layer comprises doping the second conductive layer with a second level of impurities.

3. A method according to claim 2 wherein doping the second conductive layer comprises doping the second conductive layer to the second level that is less than the first layer.

4. A method according to claim 1 wherein forming a second conductive layer comprises forming the second conductive layer at a level in the device above the first conductive layer.

5. A method according to claim 1 further comprising:
forming a first contact coupled between a bit line and a conductive region in the substrate coupled to the device including the first conductive layer; and
forming a second contact coupled between the resistor and a conductive pattern positioned at the same level with the bit line.

6. A method according to claim 1 further comprising:
forming a layer on the first conductive layer and on the substrate in the resistor region prior to forming the second conductive layer.

7. A method according to claim 6 wherein forming a layer comprises forming an etch stop layer, an insulating layer and/or a planarized interlevel dielectric layer on the first conductive layer and on the substrate in the resistor region prior to forming the second conductive layer.

8. A method according to claim 1 further comprising:
forming a device isolating layer on the substrate in the resistor region.

9. A method according to claim 6 further comprising:
forming an etch stop layer on the first conductive layer and on the resistor;
removing the etch stop layer from the first conductive layer and maintaining a portion of the etch stop layer on the resistor.

10. A method of forming a resistor in a semiconductor device comprising:
forming a first conductive layer of a gate electrode on a cell array region of a substrate of a device;
forming an etch stop layer;
forming a second conductive layer on the etch stop layer so that the first and second conductive layers are separated from one another by the etch stop layer; and
etching the second conductive layer from the first conductive layer and maintaining a portion of the second conductive layer to form a resistor on a resistor region of the substrate spaced-apart from the cell array region.

11. A method according to claim 10 wherein the etch stop layer comprises a first etch stop layer, the method further comprising:
forming a second etch stop layer on the first and second conductive layers prior to etching, wherein etching the second conductive layer comprises etching the second conductive layer and the second etch stop layer from on the first conductive layer and maintaining a portion of the second etch stop layer and second conductive layer to form the resistor in the resistor region.

12. A method according to claim 10 further comprising:
forming an interlevel dielectric layer on the etch stop layer prior to forming the second conductive layer so that the interlevel dielectric layer is located between the second conductive layer and the etch stop layer.

13. A method according to claim 12 wherein the etch stop layer comprises a first etch stop layer, the method further comprising:
forming a second etch stop layer on the second conductive layer, wherein etching the second conductive layer comprises etching the second conductive layer and the second etch stop layer from the interlevel dielectric layer over the first conductive layer and maintaining a portion of the second etch stop layer and second conductive layer to form the resistor in the resistor region.

14. A method according to claim 10 wherein forming an etch stop layer comprises forming an insulating layer.

15. A method according to claim 10 wherein forming a first conductive layer comprises doping the first conductive layer with a first level of impurities; and
wherein forming a second conductive layer comprises doping the second conductive layer with a second level of impurities.

16. A method according to claim 10 wherein forming a first conductive layer comprises forming a floating gate electrode and/or a control gate electrode.

17. A method according to claim 10 wherein forming a first conductive layer comprises forming a floating gate electrode, the method further comprising:
forming a control gate electrode on the floating comprising a third conductive layer separate from the first and second conductive layers.

18-28. (canceled)
